(19) United States
(12) Patent Application Publication
(10) Pub. No.: US 2025/0170803 A1
(43) Pub. Date: May 29, 2025

(54) LAMINATE AND ELECTRONIC DEVICE USING THE SAME

(71) Applicant: Panasonic Intellectual Property Management Co., Ltd., Osaka (JP)

(72) Inventors: Kyosuke MICHIGAMI, Tokushima (JP); Tsuyoshi TAKEDA, Osaka (JP)

(73) Assignee: Panasonic Intellectual Property Management Co., Ltd., Osaka (JP)

(21) Appl. No.: 18/956,889

(22) Filed: Nov. 22, 2024

(30) Foreign Application Priority Data
Nov. 27, 2023 (JP) 2023-199565

(51) Int. Cl. B32B 15/092; B32B 15/20

(52) U.S. Cl. CPC B32B 15/092; B32B 15/20; B32B 2250/03; B32B 2307/202; B32B 2307/51; B32B 2311/12; B32B 2363/00; B32B 2457/00

(57) ABSTRACT

The present invention relates to a laminate including a resin layer (A) and a conductive layer (B), in which the resin layer (A) is stretchable, and the conductive layer (B) is buried in the resin layer (A) and exposed on any one surface of the resin layer (A).

### FIELD OF INVENTION

The present invention relates to a laminate and an electronic device using the same.

### BACKGROUND ART

Devices and conductive materials used in the electronics field, particularly in various interfaces such as sensors, displays, and artificial skin for robots are increasingly demanded to exhibit mountability and shape followability. There is a growing demand for flexible devices that can be disposed on curved or uneven surfaces or can be freely deformed depending on the application.

A stretchable substrate used for such a flexible device has already been reported, but in the stretchable substrate, there is a risk that a wiring is disconnected due to expansion and contraction or bending of the substrate.

Therefore, in the stretchable substrate, stretchable wirings using a conductive composition containing a conductive material and an elastomer have been reported (for example, JP 2016-143763 A).

A circuit board disclosed in JP 2016-143763 A has stretchability and flexibility. Meanwhile, described in JP 2016-143763 A, when a wiring is formed on a substrate by conventional techniques, a resin layer serving as a substrate is usually formed on a support substrate, and the wiring is formed thereon.

However, when the support substrate is used, the wiring can be formed only on one surface of the substrate, and the wiring cannot be formed on the surface on the opposite side (the side where the support substrate is present), so that the number of stacked substrates is limited. Furthermore, in the circuit board described in the JP 2016-143763 A, the wiring is formed on the surface of the substrate, and thus when the wiring is not flexible, bending resistance cannot be obtained, and there is also a problem that the wiring is easily fractured. Meanwhile, when a flexible conductive paste containing an elastomer is used as the wiring, the resistance value of the wiring may be increased, or solder adhesion may be insufficient due to the influence of the elastomer when an electronic component is mounted on the wiring.

The present invention has been made in view of such circumstances, and a main object of the present invention is to provide a laminate including a wiring on a support substrate side and including a conductive layer (wiring) having excellent bending resistance.

### SUMMARY OF THE INVENTION

As a result of intensive studies, the present inventors found that the problems can be solved by the following configuration, and completed the present invention by conducting further studies based on this finding.

That is, a laminate according to one aspect of the present invention is a laminate including a resin layer (A) and a conductive layer (B), in which the resin layer (A) is stretchable, and the conductive layer (B) is buried in the resin layer (A) and exposed on any one surface of the resin layer (A).

### BRIEF DESCRIPTION OF THE DRAWINGS

FIG. 1 is a schematic cross-sectional view of a laminate according to an embodiment of the present invention;

FIG. 2 is a schematic cross-sectional view of a laminate according to another embodiment of the present invention;

FIG. 3 is a schematic cross-sectional view of a laminate according to still another embodiment of the present invention;

FIG. 4 is a schematic cross-sectional view of a laminate in which conductive layers are electrically connected to each other according to still another embodiment of the present invention;

FIG. 5 is a schematic cross-sectional view of a laminate having a multilayer structure according to still another embodiment of the present invention;

FIG. 6 is a schematic cross-sectional view of a laminate including a support substrate according to still another embodiment of the present invention;

FIG. 7 is schematic cross-sectional views showing the producing process of a laminate of an embodiment according to the present invention;

FIG. 8 is schematic cross-sectional views showing the producing process of a laminate of Example 1;

FIG. 9 is schematic cross-sectional views showing the producing process of a laminate of Example 2;

FIG. 10 is schematic cross-sectional views showing the producing process of a laminate of Example 3;

FIG. 11 is schematic cross-sectional views showing the producing process of a laminate of Example 4; and

FIG. 12 is schematic cross-sectional views showing the producing process of a laminate of Comparative Example 1.

### DETAILED DESCRIPTION

Hereinafter, a specific embodiment of the present invention will be described with reference to the drawings and the like, but the embodiment described below is merely one of various embodiments of the present invention. The following embodiment can be modified in various ways depending on the design as long as the object of the present invention can be achieved.

### Laminate of First Embodiment

First, the configuration of a laminate of a first embodiment will be specifically described. In the following description, reference numerals denote a resin layer (A) 1, a resin varnish 1′, a semi-cured film, a dry film, a conductive layer (B) 2, a second conductive layer (B′) 2′, a third conductive layer (B″) 3, a second resin layer (A′) 4, a support substrate 5, and a protective layer 6.

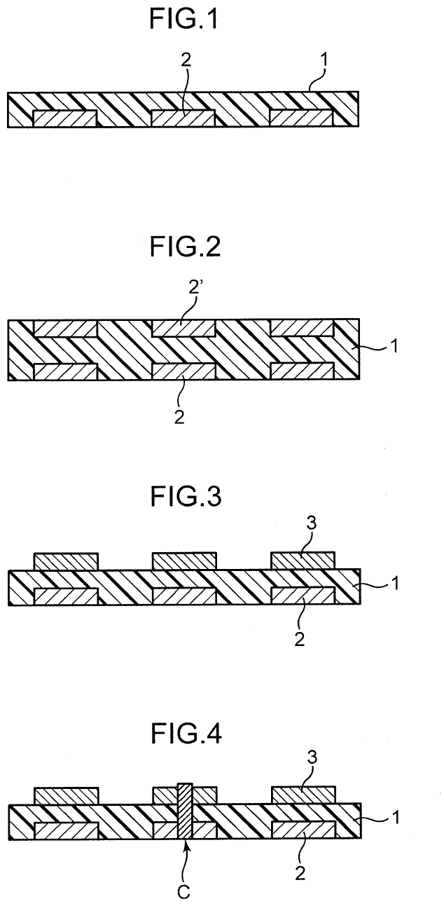

As illustrated in FIG. 1, the laminate of the first embodiment includes a resin layer (A) 1 and a conductive layer (B) 2. The resin layer (A) 1 is stretchable. The conductive layer (B) 2 is buried in the resin layer (A) 1 and exposed on any one surface of the resin layer (A) 1. According to such a configuration, it is possible to provide a laminate having a wiring on a support substrate side and including a conductive layer (wiring) having excellent bending resistance.

The fact that the resin layer (A) 1 is “stretchable” means that the resin layer (A) 1 can be stretched, and the stretchable resin layer (A) of the present embodiment preferably satisfies the following tensile modulus and/or percentage elongation after fracture. Specifically, the tensile stress of the resin layer (A) 1 at 50% elongation is preferably 0.5 MPa or more and 10 MPa or less. Alternatively, the percentage elongation after fracture is preferably 50% or more and 700% or less. It is more preferable that the stretchable resin layer is elastically deformable.

With such a configuration, a flexible laminate in which the conductive layer (B) has bending resistance is obtained. In a circuit board or the like using the laminate of the present embodiment, a wiring or a circuit can also be formed on the support substrate (release film) side in an insulating layer including the resin layer (A). Therefore, the laminate of the present embodiment can be suitably used particularly in applications such as stretchable electronic devices.

In the present embodiment, the “percentage elongation after fracture” refers to the elongation percentage until fracture, and is an index indicating the flexibility of the resin layer (A). A more preferable percentage elongation after fracture is 100% or more and 500% or less.

A laminate including the resin layer (A) having a percentage elongation after fracture within the range described above exhibits high followability when deformed into an arbitrary shape, and therefore when the laminate of the present embodiment is used as a stretchable circuit board material, it is considered that, for example, a circuit board that exhibits superior followability to clothing or the like, is less likely to be fractured, and exhibits superior stretchability can be obtained.

The percentage elongation after fracture of the present embodiment is a value measured by the following method.

First, a cured product of the resin composition to constitute the resin layer (A) is cut into a size 6 dumbbell (JIS K 6251, 2017) and attached to a universal testing machine (AGS-X manufactured by Shimadzu Corporation). Then, a test is conducted at room temperature (25° C.) and a tensile speed of 25 mm/min, and the elongation percentage when the cured product is fractured is measured with the tester and taken as “percentage elongation after fracture”.

The tensile stress at 50% elongation of the resin layer (A) refers to a tensile stress when the elongation percentage reaches 50% in the tensile test described above, and is an index indicating the flexibility of the resin layer (A) together with the percentage elongation after fracture described above. Within the range described above, high followability is exhibited at the time of deformation into an arbitrary shape, and therefore there is an advantage that when the laminate of the present embodiment is used as a stretchable circuit board material or the like, wirings and component mounted portions are less likely to be fractured. A more preferable range of the tensile stress is 1.0 MPa or more and 5 MPa or less.

In the present embodiment, the tensile stress is a value measured by the following method.

In the same manner as in the measurement of the percentage elongation after fracture described above, a cured product of the resin composition to constitute the resin layer (A) is cut into a size 6 dumbbell (JIS K 6251, 2017) and attached to a universal testing machine (AGS-X manufactured by Shimadzu Corporation). Then, a test is conducted at room temperature (25° C.) and a tensile speed of 25 mm/min, and a stress value when the tensile elongation percentage reaches 50% is calculated.

Stress (σ)=F/(d·1) (F is test force, d is film thickness, and 1 is width of test piece)

Hereinafter, each configuration of the laminate of the present embodiment will be described.

### Resin Layer (A)

The resin component in the resin composition to be used for the resin layer (A) of the present embodiment is not particularly limited as long as a cured product of the resin composition has stretchability, but for example, the resin component is preferably such a resin component that the tensile stress at 50% elongation is 0.5 MPa or more and 10 MPa or less and/or the percentage elongation after fracture is 50% or more and 700% or less in the cured product.

The resin layer (A) of the present embodiment is preferably composed of a cured product of a curable resin composition or a thermoplastic resin composition. Examples of the resin contained in the curable resin composition or the thermoplastic resin composition include thermoplastic resins and thermosetting resins. Examples of the thermoplastic resin include urethane resins, various kinds of rubber, acrylic resins, olefin-based resins, ethylene propylene diene rubber, isoprene rubber, butadiene rubber, and chloroprene rubber. In the present embodiment, it is particularly preferable to use a curable resin composition containing a thermosetting resin from the viewpoint of excellent adhesiveness and heat resistance, and from the viewpoint of being able to impart functions such as chemical resistance. As the thermosetting resin, it is preferable to use at least one selected from epoxy resins, urethane resins, silicone resins, polyrotaxane resins, isocyanate resins, polyol resins, styrene-based elastomer resins, and acrylic acid ester copolymer resins. Among them, it is more preferable to use epoxy resins, polyrotaxane resins, and styrene-based elastomer resins and the like. These resins may be used singly or in combination of two or more kinds thereof.

Furthermore, the resin composition may contain various additives such as a curing agent, a curing accelerator, a filler, an antioxidant, a leveling agent, a pigment, and a dye agent as long as the effects of the present invention are not impaired. In particular, when a styrene-based elastomer resin is used, it is preferable to add an organic peroxide as an additive to the resin composition. As a result, a crosslinked structure is formed and heat resistance is obtained, so that the deformation of the resin layer and the conductive layer in a high temperature environment can be suppressed. In this case, as the organic peroxide, an organic peroxide that can be used as a radical polymerization initiator can be used without particular limitation.

In the laminate of the present embodiment, the thickness of the resin layer (A) can be appropriately set depending on the application and the like of the laminate, and is, for example, about 0.01 mm or more and 1 mm or less. Furthermore, the thickness of the resin layer (A) is preferably 0.02 mm or more and 0.2 mm or less. When the thickness is smaller than that, the handleability is deteriorated, and the strength of the resin layer is also deteriorated. Meanwhile, when the thickness is larger than that, bubbles are likely to be generated, and the resin layer is hard and flexibility as a device deteriorates. In addition, it is also disadvantageous when conduction occurs across the resin layer.

Conductive layer (B)

The conductive layer (B) 2 buried in the resin layer (A) may be stretchable or non-stretchable, but is preferably composed of a conductive material containing at least one selected from a conductive resin composition or a metal. Note that the conductive layer (B) 2 may be a circuit formed in a pattern as shown in FIG. 1.

A part of the conductive layer (B) 2 buried in the resin layer (A) is exposed on any one surface of the resin layer (A) 1. For example, in FIG. 1, the surface is exposed from the bottom surface of the resin layer (A). The portion exposed from the resin layer (A) may be only the surface of the conductive layer (B), or the side surface may be partially exposed in addition to the surface of the conductive layer (B). The same applies to not only the first embodiment but also other embodiments to be described later.

In the present embodiment, examples of the stretchable conductive material include a conductive resin composition (conductive paste). Examples of the conductive resin composition that can be used in the present embodiment include a conductive resin composition containing a binder resin composed of a thermosetting resin and/or a thermoplastic resin and conductive particles. Examples of the thermosetting resin include a silicone resin, a urethane resin, an epoxy resin, an acrylic resin, and a fluororubber, and examples of the thermoplastic resin include a urethane resin, an acrylic resin, an olefin-based resin, an ethylene propylene diene rubber, an isoprene rubber, a butadiene rubber, a chloroprene rubber, a nitrile rubber, and a polyester resin. In particular, from the viewpoint of adhesion to the adhesive layer and the conductive layer, it is preferable to use a urethane resin, an epoxy resin, an acrylic resin, an olefin-based resin, an ethylene propylene diene rubber, an isoprene rubber, a butadiene rubber, a chloroprene rubber, a nitrile rubber, or a polyester resin, and it is more preferable to use an acrylic resin, an epoxy resin, a urethane resin, a polyester resin, or a nitrile rubber.

Specific examples of the conductive particles include particles composed of silver, silver-coated copper (including a configuration in which a part of the surface of copper is coated with silver), copper, gold, carbon particles, carbon nanotubes, a conductive polymer, tin, bismuth, indium, gallium, nickel, aluminum, or an alloy of these metals.

As described above, examples of the conductive resin composition of the present embodiment include stretchable epoxy resins, acrylic resins, urethane resins, silicone resins, fluororesins, styrene-butadiene copolymer resins, polyester resins, and silver pastes and silver inks obtained by combining various rubbers with silver powder, silver flakes, and the like.

Examples of the non-stretchable conductive material include metals, and more specific examples thereof include copper (including a surface treatment with gold or the like), aluminum, and nickel.

Alternatively, the conductive layer (B) may be composed of a sintered body of metal particles or the like. The sintered body is obtained by heating fine particles of silver, copper, gold, or the like at an appropriate firing temperature to melt the particles or the surfaces of the particles to dissolve the particles or the surfaces of the particles in a solid solution, and is obtained by printing, heating, drying, and firing a metal particle-dispersed ink in which the fine particles are dispersed in water or an organic solvent.

In a preferred embodiment, the conductive layer (B) is non-stretchable. When the stretchable conductive resin composition as described above is used, the resistance value may be increased, and the solder adhesion may be insufficient due to the influence of the resin component contained in the composition. Therefore, it is preferable that the conductive layer (B) is non-stretchable from the viewpoint of suppressing the resistance value of the wiring and circuit or solder adhesion when the electronic component is mounted by solder. Usually, when the resin layer (A) is stretchable and the conductive layer (B) is non-stretchable, the bending resistance of the conductive layer (B) is deteriorated, and the wiring and the circuit may be fractured. However, in the laminate of the present embodiment, the conductive layer (B) is buried in the resin layer (A), so that such fracture and the like can be suppressed.

The thicknesses of the substrate and the conductive layer (B) of the present embodiment are not particularly limited, but are usually about 0.01 μm or more and 50 μm or less. A more preferable thickness is about 1 μm or more and 35 μm or less.

### Laminate of Second Embodiment

As shown in FIG. 2, in addition to the configuration of the laminate of the first embodiment, the laminate of the second embodiment further includes a second conductive layer (B′) 2′ that is buried in the resin layer (A) 1 as with the conductive layer (B) 2 and is exposed on a surface of the resin layer (A) 1 on a side opposite to a surface where the conductive layer (B) 2 is exposed. The second conductive layer (B′) 2′ may also be a circuit patterned as shown in FIG. 2.

The second conductive layer (B′) 2′ of the second embodiment may be a non-stretchable conductive layer similar to the conductive layer (B) described in the first embodiment or a stretchable conductive layer. The second conductive layer (B′) 2′ and the conductive layer (B) 2 may have the same configuration or different configurations. That is, for example, when the conductive layer (B) is non-stretchable, the second conductive layer (B′) 2′ may be similarly a non-stretchable conductive layer, or may be a stretchable conductive layer different from the non-stretchable conductive layer. In a preferred embodiment, the second conductive layer (B′) 2′ of the second embodiment is non-stretchable, and thus the laminate of the second embodiment also has the same advantage as that in the case where the conductive layer (B) is non-stretchable in the first embodiment.

### Laminate of Third Embodiment

As shown in FIG. 3, in addition to the configuration of the laminate of the first embodiment, a laminate of a third embodiment further includes a second conductive layer (B′) 3 that is formed on a surface of the resin layer (A) on a side opposite to a surface where the conductive layer (B) is exposed. The second conductive layer (B′) 3 may also be a circuit patterned as shown in FIG. 3.

The second conductive layer (B′) 3 in the laminate of the third embodiment is different from the second conductive layer (B′) of the second embodiment, is not buried in the resin layer (A), and is formed on the surface of the resin layer (A).

The second conductive layer (B′) 3 in the third embodiment may be a non-stretchable conductive layer similar to the conductive layer (B) described in the first embodiment or a stretchable conductive layer. The second conductive layer (B′) 3 and the conductive layer (B) 2 may have the same configuration or different configurations. That is, for example, when the conductive layer (B) is non-stretchable, the second conductive layer (B′) 3 may be similarly a non-stretchable conductive layer, or may be a stretchable conductive layer different from the non-stretchable conductive layer. In a preferred embodiment, the second conductive layer (B′) 3 in the third embodiment is preferably stretchable because the second conductive layer (B′) 3 is formed on the resin layer (A). This is because the second conductive layer (B′) 3 exposed on the resin layer (A) can have bending resistance.

### Laminate of Fourth Embodiment

In a laminate of a fourth embodiment, the conductive layer (B) and the second conductive layer (B′) are conductive in the laminate including the second conductive layer (B′) as in the second embodiment or the third embodiment. For example, FIG. 4 shows a laminate of the third embodiment in which the conductive layer (B) 2 and the second conductive layer (B′) 3 are conductive at a position indicated by C. Although FIG. 4 shows conduction in the laminate of the third embodiment, the conductive layer (B) 2 and the second conductive layer (B′) 2′ can also be conducted in the laminate of the second embodiment.

### Laminate of Fifth Embodiment

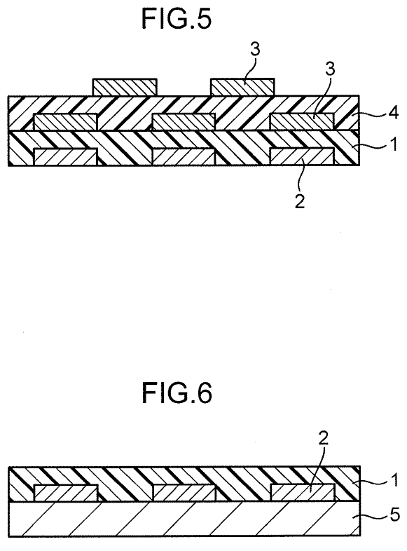

As shown in FIG. 5, a laminate of a fifth embodiment further includes a second resin layer (A′) 4 on the resin layer (A) 1 in addition to the configuration of the laminate of the first embodiment, and the second conductive layer (B′) 2′ is buried in the second resin layer (A′) 4. The laminate further includes a third conductive layer (B″) 3 formed on a surface of the second resin layer (A′) 4 on a side opposite to a surface in which the conductive layer (B′) 2′ is buried. The third conductive layer (B″) 3 may also be a circuit patterned as shown in FIG. 5.

The second resin layer (A′) 4 is preferably provided on a surface of the resin layer (A) 1 on a side opposite to a surface in which the conductive layer (B) is buried.

The second resin layer (A′) 4 may be made of the same material as that of the resin layer (A) 1, or may be made of a cured product of a different resin composition. The second resin layer may be stretchable or non-stretchable, and stretchable and non-stretchable resin layers may be mixed. Preferably, the second resin layer desirably has stretchability similarly to the resin layer (A) 1, but for example, a portion where an electronic component is mounted may be formed of a non-stretchable resin layer.

When the second resin layer (A′) 4 is stretchable, the second resin layer (A′) 4 may be composed of a cured product of a resin composition similar to that of the resin layer (A) 1 described in the first embodiment. Meanwhile, when the second resin layer (A′) 4 is non-stretchable, a resin that can be used as an insulating layer of a so-called rigid substrate can be used as a main component. Specifically, examples thereof include resins such as polyimide, polyetherimide, polyethylene terephthalate, polybutylene terephthalate, polyethylene naphthalate, potiethylene, polypropylene, polycarbonate, polyvinyl chloride, polyvinylidene chloride, polyvinyl alcohol, ponyphenylene ether, vinylon, cellulose, cellulose acetate, polyolefin, polystyrene, polyacrylate, triacetate, nylon, aramid, polyethersulfone, polyphenylsulfide, polyetheretherketone, polyacetal, norbornene resin, fluororesin, polymethylpentene resin, styrene-butadiene-acrylonitrile copolymer, ethylene-vinyl acetate copolymer, styrene-acrylonitrile copolymer, ethylene tetrafluoride-propylene hexafluoride copolymer, ethylene tetrafluoride-perfluoroalkoxyethylene copolymer, ethylene tetrafluoride-ethylene copolymer, and vinylidene fluoride. The resin as described above may be laminated with fibers or the like.

The second conductive layer (B′) 2′ may be a non-stretchable conductive layer similar to the conductive layer (B) described in the first embodiment or a stretchable conductive layer. The second conductive layer (B′) 2′ and the conductive layer (B) 2 may have the same configuration or different configurations. That is, for example, when the conductive layer (B) is non-stretchable, the second conductive layer (B′) 2′ may be similarly a non-stretchable conductive layer, or may be a stretchable conductive layer different from the non-stretchable conductive layer. In a preferred embodiment, the second conductive layer (B′) 2′ of the second embodiment is non-stretchable, and thus the laminate of the second embodiment also has the same advantage as that in the case where the conductive layer (B) is non-stretchable in the first embodiment.

The third conductive layer (B″) 3 may be a non-stretchable conductive layer similar to the conductive layer (B) described in the first embodiment or a stretchable conductive layer. The second conductive layer (B′) 3 and the conductive layer (B) 2 may have the same configuration or different configurations. That is, for example, when the conductive layer (B) is non-stretchable, the second conductive layer (B′) 3 may be similarly a non-stretchable conductive layer, or may be a stretchable conductive layer different from the non-stretchable conductive layer. In a preferred embodiment, the second conductive layer (B′) 3 in the fifth embodiment is preferably stretchable because the second conductive layer (B′) 3 is formed on the second resin layer (A′) 4. This is because the second conductive layer (B′) 3 exposed on the resin layer (A) can have bending resistance.

The second conductive layer (B′) 2′ and/or the third conductive layer (B″) 3 is preferably appropriately selected depending on the material constituting the second resin layer (A′) 4. That is, when the second resin layer (A′) 4 is made of a non-stretchable material, the second conductive layer (B′) 2′ and the third conductive layer (B″) 3 preferably have stretchability. Meanwhile, when the second resin layer (A′) 4 is made of a stretchable material, at least the conductive layer (B′) 2′ may be non-stretchable. However, the third conductive layer (B″) 3 is preferably stretchable because it is exposed on the resin layer in any case.

### Laminate of Sixth Embodiment

A laminate of a sixth embodiment further includes a support substrate (C) in addition to the configurations of the laminates of the first to fifth embodiments. FIG. 6 shows, as an example, a laminate including a support substrate (C) 5 in the laminate of the first embodiment.

Examples of the support substrate (C) that can be used include, but are not particularly limited to, a film used as a release film, and specific examples thereof include electrical insulating films such as a polyimide film, a polyamide film, a polyethylene terephthalate (PET) film, a polyethylene naphthalate (PEN) film, a polyester film, a poly(parabanic acid) film, a polyether ether ketone film, a polyphenylene sulfide film, an aramid film, a polycarbonate film, and a polyarylate film.

Although not illustrated, the laminate of the present embodiment may further include a protective layer (D) on the opposite side of the support substrate (C) in addition to the support substrate (C). As the protective layer (D), a film generally used as a cover film can be used without particular limitation, and examples thereof include electrically insulating films such as a polyethylene naphthalate (PEN) film, a polyimide film, a polyamide film, a polyethylene terephthalate (PET) film, a polyester film, a polyparabanic acid film, a polyether ether ketone film, a polyphenylene sulfide film, an aramid film, a polycarbonate film, a polyarylate film, a polyethylene film, and a polypropylene film.

The laminate of the present embodiment described above can be used for various applications, and for example, can be suitably used as a material of an electronic device, particularly a circuit board.

### (Method for Producing Laminate)

Next, a method for producing the laminate of the present embodiment will be described. The method for producing the laminate of the present embodiment can be used without particular limitation as long as it is a method for obtaining the laminate as described above.

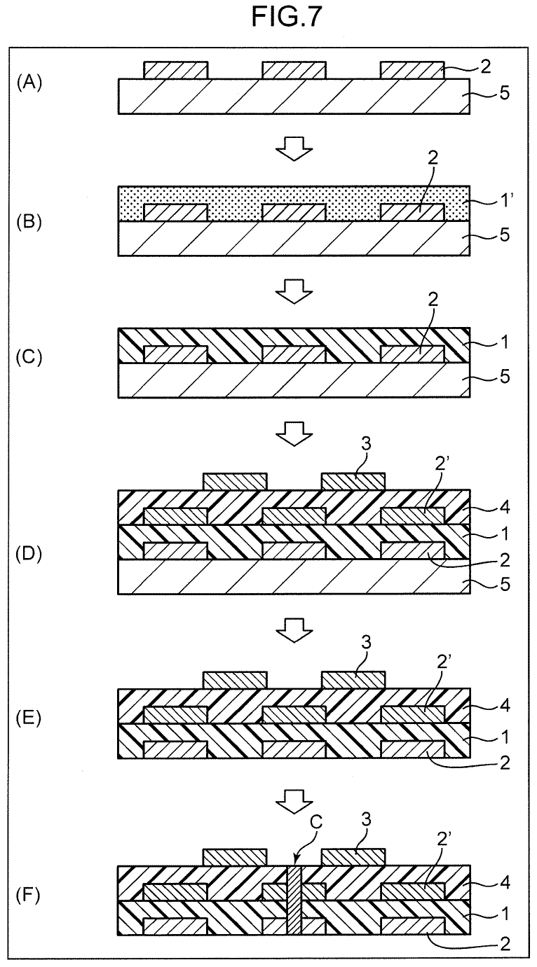

For example, FIG. 7 is a view showing an example of a method for producing a laminate of the present embodiment. First, as shown in FIG. 7A, a conductive layer (B) 2 is formed on a support substrate (C) 5. The conductive layer (B) 2 may be a circuit formed in a pattern as shown in FIG. 7A. The method for forming the circuit is also not particularly limited, and for example, the circuit (wiring) can be formed by performing etching processing or the like on the conductive layer (B) formed of a metal foil provided on the support substrate (C) 5. Examples of the circuit forming method include circuit formation by a semi additive process (SAP) or a modified semi additive process (MSAP) in addition to the method described above.

Alternatively, a method for forming a circuit using a conductive composition or the like can be performed by, for example, a printing method or the like. Specifically, when the conductive layer (B) 2 is composed of a paste of a conductive resin composition, a circuit having a desired pattern can be formed by printing and applying the conductive layer (B) 2 on the support substrate (C) 5 by a printing method such as screen printing, inkjet printing, gravure printing, or offset printing.

When the conductive layer (B) is composed of a sintered body of metal particles, for example, a circuit pattern can be formed on the support substrate (C) 5 by printing an ink (metal particle-dispersed ink) containing the sintered body of metal particles as described above by inkjet or the like, followed by heating, drying, and firing.

In addition to the above, examples of a method for forming the circuit pattern of the conductive layer (B) 2 include a method for forming the circuit pattern by electrolysis or electroless plating, and a method for forming the circuit pattern by depositing a metal.

Next, as shown in FIG. 7B, a resin varnish 1′ of the resin composition constituting the resin layer (A) is applied onto the support substrate (C) 5 on which the circuit pattern of the conductive layer (B) 2 has been formed so as to have a desired thickness. Examples of the application method include a bar coater, a comma coater, a die coater, a roll coater, and a gravure coater. The material used for forming the resin layer (A) is not limited to the resin varnish, and a semi-cured product of the resin composition or a dry film may be bonded onto the support substrate (C) 5 on which the circuit pattern of the conductive layer (B) 2 is formed.

Such a resin varnish is prepared, for example, as follows. First, components that can be dissolved in an organic solvent, such as a resin component (a thermosetting resin or various additives), are added to an organic solvent to be dissolved. At this time, heating may be performed, if necessary. Thereafter, components (for example, inorganic filler) insoluble in the organic solvent are added, if necessary, and dispersed in the solution until a prescribed dispersion state is achieved using a disper, a ball mill, a bead mill, a planetary mixer, or a roll mill or the like, whereby a varnish-like resin composition is prepared. The organic solvent used here is not particularly limited as long as it dissolves the resin component and the additive and the like and does not inhibit the curing reaction. Specific examples thereof include toluene, methyl ethyl ketone, cyclohexanone and propylene glycol monomethyl ether acetate. These solvents may be used singly or two or more thereof may be used in combination. A part or all of the solvent may be replaced with a reactive diluent. Examples of the reactive diluent include styrene, butyl acrylate, butyl methacrylate, butyl glycidyl ether, and 1,2-dodecene.

Thereafter, as shown in FIG. 7C, the applied and dried resin layer 1′ in the case of containing a solvent is cured by heating and pressurizing under desired conditions, for example, at a pressure of about 0.1 MPa or more and 20 MPa or less and a temperature of 50 to 220° C. for 1 minute to 2 days, thereby forming a resin layer (A) 1. At this stage, the laminate with the support substrate (C) of the sixth embodiment is obtained. When the support substrate (C) is peeled off from the laminate, the laminate of the first embodiment is obtained. The pressure is preferably 0.3 MPa or more and 10 MPa or less, and more preferably 1.0 MPa or more and 5 MPa or less from the viewpoint of burying the conductive layer and suppressing the resin flow. The temperature is preferably 80° C. or higher and 220° C. or lower, and more preferably 130° C. or higher and 200° C. or lower from the viewpoint of increasing the fluidity of the resin to bury the conductive layer and accelerating curing. In addition, it is preferable that vacuum is applied at the time of heating and pressurization. As a result, the oxidation of the conductive layer can be suppressed.

When the resin layer before curing exhibits fluidity, the resin layer (A) 1 can also be formed by curing at a temperature of 0 to 220° C. for 1 minute to 2 days without pressurization. The temperature is more preferably 20° C. or higher and 220° C. or lower from the viewpoint of accelerating curing.

Furthermore, in the case of producing a multilayer laminate, as shown in FIG. 7D, the second conductive layer (B′) 2′ may be formed on the resin layer (A) 1 of the laminate obtained above. The method for forming the second conductive layer (B′) 2′ can be performed in the same manner as the conductive layer (B) 2. At this stage, when the support substrate (C) 5 is peeled off, the laminate of the third embodiment can be obtained.

Next, a second resin layer (A′) 4 may be formed on the resin layer (A) 1 on which the circuit pattern of the second conductive layer (B′) 2′ is formed. In this case, the second conductive layer (B′) 2′ is buried in the second resin layer (A′) 4. The second resin layer (A′) 4 can be formed in the same manner as the resin layer (A) 1.

Furthermore, after the second resin layer (A′) 4 is formed, a third conductive layer (B″) 3 can be formed thereon. The third conductive layer (B″) 3 can be formed in the same manner as the conductive layer (B) 2.

By peeling off the support substrate (C) 5 from the obtained multilayer laminate, as shown in FIG. 7E, the laminate of the fifth embodiment can be obtained.

Furthermore, in the obtained multilayer laminate, as shown in FIG. 7F, conductive layers can be made conductive. In FIG. 7F, conduction is established between the conductive layer (B) 2 and the second conductive layer (B′) 2′, but conduction can be performed between desired conductive layers. The conducting method is not particularly limited, and the conductive layers can be conducted by, for example, a method such as crimping, rivets, through-hole plating, blind via holes, connection columns filled with a conductive paste, an anisotropic conductive film (ACF), a conductive adhesive, connection by a wiring, or connection by electronic components.

### (Electronic Device)

The present embodiment also includes an electronic device in which an electronic component is further mounted on the laminate described above.

The electronic component that can be mounted in the present embodiment is not particularly limited, and examples thereof include wireless modules such as resistances, transistors, signal transmission elements, light emitting elements, solar power generation elements, diodes, switching elements, capacitors, coils, liquid crystals, and Bluetooth (registered trademark), various sensors such as acceleration sensors, humidity sensors, and temperature sensors, chip parts to be used for RFIDs and the like.

The electronic component can be mounted by, for example, a mounting method using a conductive pressure-sensitive adhesive or an adhesive or a mounting method using solder and reflow. In addition, it is also possible to print and form an element on the resin layer (A) or the conductive layer (B) of the laminate instead of the solder.

This specification discloses techniques in various aspects as described above, and the main techniques among them are summarized below.

A laminate according to a first aspect of the present invention is a laminate including a resin layer (A) and a conductive layer (B), wherein the resin layer (A) is stretchable, and the conductive layer (B) is buried in the resin layer (A) and exposed on any one surface of the resin layer (A).

A laminate according to a second aspect is the laminate of the first aspect, wherein the conductive layer (B) contains silver or copper.

A laminate according to a third aspect is the laminate of the first aspect, wherein the conductive layer (B) is non-stretchable.

A laminate according to a fourth aspect is the laminate of the first aspect, wherein a tensile stress of the resin layer (A) at 50% elongation is 0.5 MPa or more and 100 MPa or less.

A laminate according to a fifth aspect is the laminate of the first aspect, wherein the resin layer (A) has a percentage elongation after fracture of 50% or more and 700% or less.

A laminate according to a sixth aspect is the laminate of the first aspect, wherein the laminate further includes a second conductive layer (B′) buried in the resin layer (A) and exposed on a surface of the resin layer (A) opposite to a surface where the conductive layer (B) is exposed in the laminate of the first aspect.

A laminate according to a seventh aspect is the laminate of the sixth aspect, wherein the second conductive layer (B′) is non-stretchable.

A laminate according to an eighth aspect is the laminate of the first aspect, wherein the laminate further includes a second conductive layer (B′) formed on a surface of the resin layer (A) on a side opposite to a surface where the conductive layer (B) is exposed in the laminate of the first aspect.

A laminate according to a ninth aspect is the laminate of the eighth aspect, wherein the second conductive layer (B′) is stretchable.

A laminate according to a tenth aspect is the laminate of the eighth aspect, wherein at least a part of the conductive layer (B) and at least a part of the second conductive layer (B′) are conductive.

A laminate according to an eleventh aspect is the laminate of the first aspect, wherein the laminate further includes a second resin layer (A′) on the resin layer (A), wherein the second conductive layer (B′) is buried in the second resin layer (A′), and the laminate further includes a third conductive layer (B″) formed on a surface of the second resin layer (A′) on a side opposite to a surface in which the conductive layer (B′) is buried, in the laminate of the first aspect.

A laminate according to a twelfth aspect is the laminate of the first aspect, wherein the laminate further includes a support substrate (C).

A laminate according to a thirteenth aspect is the laminate of the first aspect, wherein the laminate further includes a protective layer (D).

An electronic device according to a fourteenth aspect includes: the laminate according to any one of the first to thirteenth aspects; and an electronic component.

Hereinafter, the present invention will be described more specifically with reference to Examples, but the scope of the present invention is not limited thereto.

### EXAMPLES

First, a resin composition (varnish) for forming a resin layer was prepared.

### Production Example 1

In a solvent (MEK/toluene (mass ratio: 4/6)), 100 parts by mass of polyrotaxane “SH3400P” (manufactured by ASM), 90 parts by mass of an epoxy resin “JER1003” (manufactured by Mitsubishi Chemical Corporation), 2 parts by mass of monofunctional acid anhydride “YH-307” (manufactured by Mitsubishi Chemical Corporation) as a curing agent, and 1 part by mass of an imidazole-based curing accelerator “2E4MZ” (manufactured by Shikoku Chemicals Corporation) were dissolved with stirring to prepare a resin varnish having a concentration of 50% by mass. After being left to stand and defoamed, the resin varnish was applied to a release-treated PET film (“SP-PET O1” manufactured by Mitsui Chemicals Tohcello, Inc.) as a protective layer using a bar coater. Then, the film was dried in an oven at 80° C. for 10 minutes to obtain a dried film A composed of a dried product of the resin composition. The dried film A was heated in an oven at 160° C. for 5 minutes to obtain a semi-cured film (thickness: 100 μm) composed of a semi-cured product of the resin composition.

### Production Example 2

99 parts by mass of a styrene-isoprene-styrene (SIS) block copolymer “Hibler (registered trademark) 5125” (manufactured by Kuraray Co., Ltd.) and 1 part by weight of (1,3-bis(butylperoxyisopropyl)benzene “Perbutyl (registered trademark) P” (manufactured by NOF CORPORATION) as an organic peroxide were dissolved in 200 parts by weight of toluene to prepare a resin varnish. Next, the resin varnish was applied to a release-treated PEN film “J0” (manufactured by Nippa Co., Ltd.) as a protective layer, dried at 80° C. for 10 minutes, and then dried at 110° C. for 10 minutes to prepare a dry film (thickness: 100 μm).

### <Method for Producing Laminate>

### Example 1

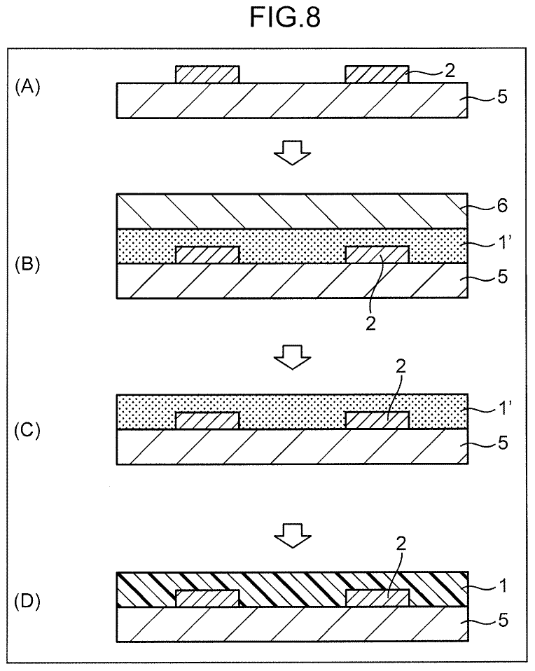

A producing process of a laminate of Example 1 is shown in FIG. 8. First, as shown in FIG. 8A, a circuit pattern was screen-printed using a copper ink “LF360” (manufactured by Copprint) on a 50 μm release-treated polyimide film “J0” (manufactured by Nippa Co., Ltd.) as a support substrate 5, and dried at 90° C. for 2 minutes to form a conductive layer 2. The conductive layer had a line width of 1 mm, a length of 10 cm, and a thickness of 20 μm. Next, as shown in FIG. 8B, a semi-cured film 1′ (with a protective layer 6) of the resin composition of Production Example 1 was laminated on the polyimide film 5 on which the conductive layer 2 was formed at 40° C. and 0.3 MPa for 60 seconds using a vacuum laminator. Then, the protective layer 6 (PEN film) was peeled off (FIG. 8C). Subsequently, the semi-cured film 1′ was cured by heating in an oven at 160° C. for 1 hour to form a resin layer 1, thereby obtaining a laminate of Example 1 (with the support substrate 5) (FIG. 8D).

### Example 2

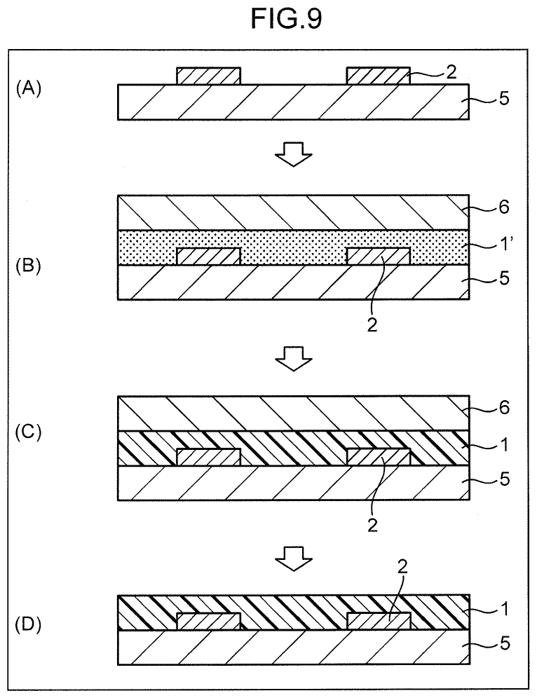

A producing process of a laminate of Example 2 is shown in FIG. 9. First, as shown in FIG. 9A, a circuit pattern was screen-printed using a copper ink “LF360” (manufactured by Copprint) on a 50 μm release-treated polyimide film “J0” (manufactured by Nippa Co., Ltd.) as a support substrate 5, and dried at 90° C. for 2 minutes to form a conductive layer 2. The conductive layer had a line width of 1 mm, a length of 10 cm, and a thickness of 20 μm. Next, as shown in FIG. 9B, the dry film 1′ (with the protective layer 6) of Production Example 2 was laminated at 80° C. and 0.3 MPa for 60 seconds using a vacuum laminator. Thereafter, the dry film 1′ was cured by heat-pressing at 4 MPa and 180° C. for 30 minutes to form a resin layer 1 (FIG. 9C). Then, the protective layer 6 (PEN film) was peeled off to obtain a laminate (with the support substrate 5) of Example 2 (FIG. 9D).

### Example 3

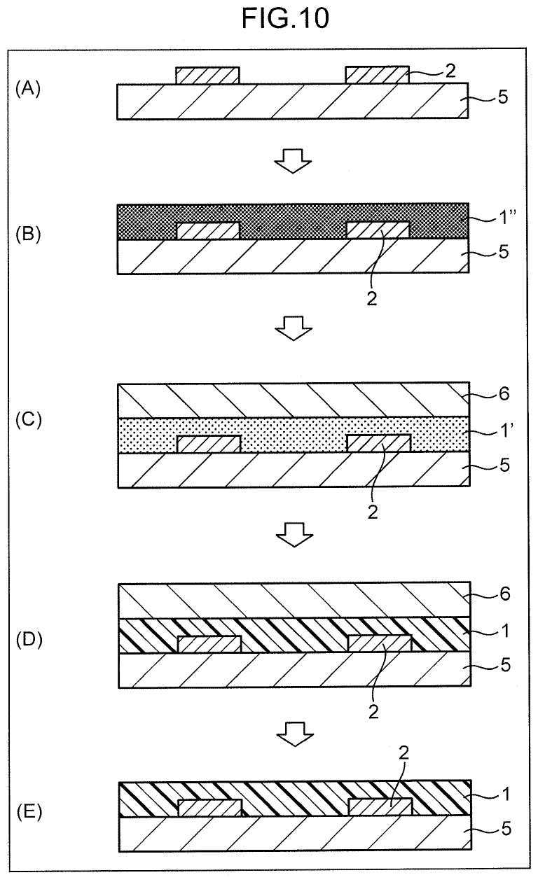

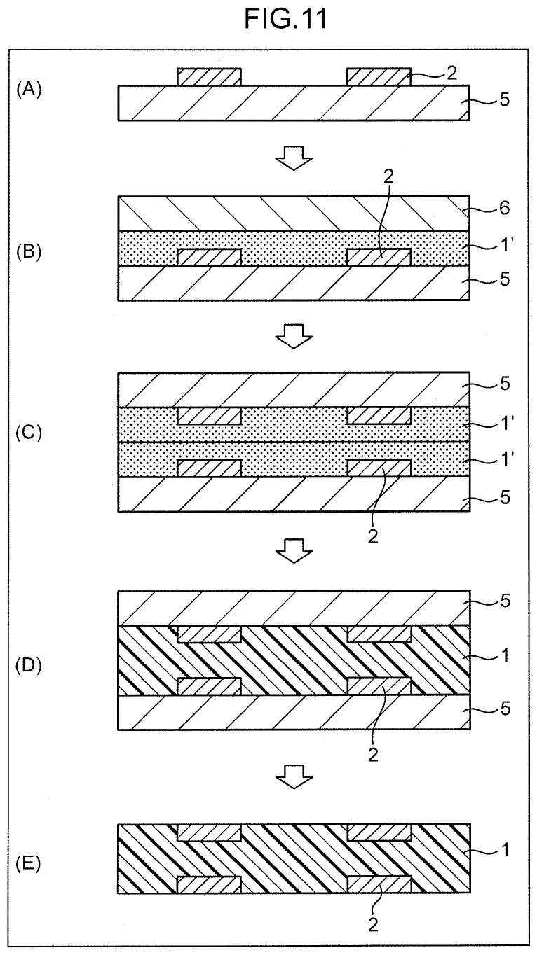

A producing process of a laminate of Example 3 is shown in FIG. 10. First, as shown in FIG. 10A, a circuit pattern was screen-printed using a copper ink “LF360” (manufactured by Copprint) on a 50 μm release-treated polyimide film “J0” (manufactured by Nippa Co., Ltd.) as a support substrate 5, and dried at 90° C. for 2 minutes to form a conductive layer 2. The conductive layer had a line width of 1 mm, a length of 10 cm, and a thickness of 20 μm. Next, as shown in FIG. 10B, the resin varnish 1″ of Production Example 2 was applied so that a thickness after drying was 100 μm, and dried at 80° C. for 10 minutes and then at 110° C. for 10 minutes. Thereafter, a release-treated PEN film “J0” (manufactured by manufactured by Nippa Co., Ltd.) as a protective layer 6 was laminated on the resin surface (FIG. 10C), and heated and pressed at 4 MPa for 30 minutes at 180° C. to cure the resin varnish 1″, thereby forming a resin layer 1 (FIG. 10D). Then, the protective layer 6 (PEN film) was peeled off to obtain a laminate (with the support substrate 5) of Example 3 (FIG. 10E).

### Example 4

A producing process of a laminate of Example 4 is shown in FIG. 11. First, as shown in FIG. 11A, a circuit pattern was screen-printed using a copper ink “LF360” (manufactured by Copprint) on a 50 μm release-treated polyimide film “J0” (manufactured by Nippa Co., Ltd.) as a support substrate 5, and dried at 90° C. for 2 minutes to form a conductive layer 2. The conductive layer had a line width of 1 mm, a length of 10 cm, and a thickness of 20 μm. Next, as shown in FIG. 11B, the dry film 1′ (with the protective layer 6) of Production Example 2 was laminated at 80° C. and 0.3 MPa for 60 seconds using a vacuum laminator. Then, the protective layer 6 (PEN film) was peeled off from the dry film 1′. The steps of FIGS. 11A to 11C were repeated to prepare another dry film 1′ from which the protective layer 6 had been peeled off, and as shown in FIG. 11C, two dry films 1′ with the support substrate 5 (polyimide film) were stacked with the resin sides facing each other, and laminated at 80° C. and 0.3 MPa for 60 seconds using a vacuum laminator. Thereafter, the dry film 1′ was cured by heat-pressing at 4 MPa and 180° C. for 30 minutes to form a resin layer 1 (FIG. 11D). Then, the support substrate 5 (polyimide film) was peeled off to obtain a laminate of Example 4 (FIG. 11E).

### Comparative Example 1

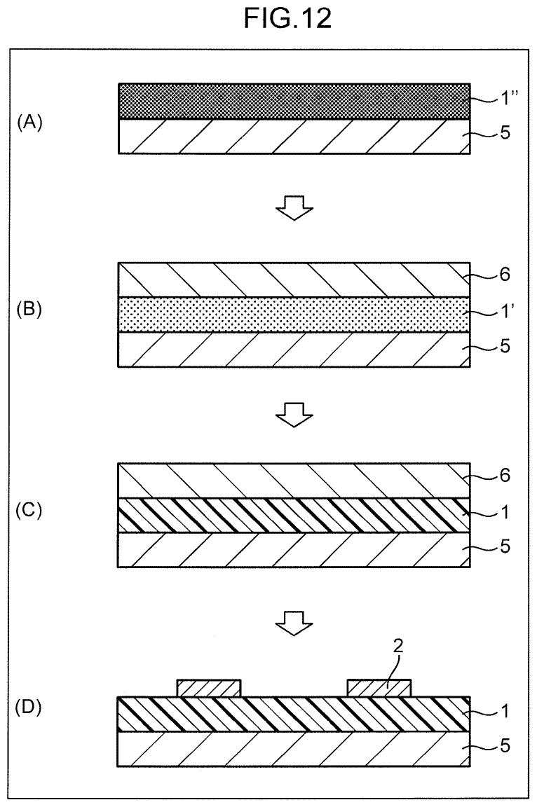

A producing process of a laminate of Comparative Example 1 is shown in FIG. 12. First, as shown in FIG. 12A, the resin varnish 1″ of Production Example 2 was applied onto a release-treated polyimide film “J0” (manufactured by Nippa Co., Ltd.) having a thickness of 50 μm as a support substrate 5 so as to have a thickness of 100 μm after drying, and dried at 80° C. for 10 minutes and then at 110° C. for 10 minutes. The conductive layer had a line width of 1 mm, a length of 10 cm, and a thickness of 20 μm.

Thereafter, as shown in FIG. 12B, a PEN film “SP3030” (manufactured by Toyo Cloth Co., Ltd.) release-treated as a protective layer 6 was laminated on the dried resin varnish layer 1′. Then, the resin varnish layer 1′ was cured by heat-pressing at 4 MPa and 180° C. for 30 minutes to form a resin layer 1 (FIG. 12C). As shown in FIG. 12D, the protective layer 6 (PEN film) was peeled off, and a circuit pattern was screen-printed using a copper ink “LF360” (manufactured by Copprint), dried at 90° C. for 2 minutes, and then heat-pressed at 4 MPa for 180° C. for 30 minutes to form a conductive layer 2, thereby obtaining a laminate of Comparative Example 1.

### <Evaluation>

### (Bending Resistance of Conductive Layer)

A cylindrical SUS rod having a diameter of 2 mm was prepared, and in each of the laminates of Examples and Comparative Examples, the SUS rod was perpendicularly applied to a linear wiring having a width of 1 mm formed using each conductive layer, and bent at 90°. At this time, it was confirmed whether or not the wiring was cracked. As a result, cracks were not generated in the laminates of Examples 1 to 4, whereas cracks were generated in the wiring in the laminate of Comparative Example 1.

### DISCUSSION

First, in the laminate according to the present invention, as shown in FIGS. 8 to 11 (Examples 1 to 4), a circuit can be formed on the back surface of the resin layer, but in Comparative Example 1, a circuit cannot be formed on the back surface of the resin layer.

In the laminates of Examples 1 to 4, the conductive layer had bending resistance, but in the laminate in which the conductive layer was not buried in the resin layer as in Comparative Example 1, cracks were generated in the bending test.

This application is based on Japanese Application No. 2023-199565 filed in the Japanese Patent Office on Nov. 27, 2023, the contents of which are hereby incorporated by reference.

Although the present invention has been fully described by way of example with reference to the accompanying drawings, it is to be understood that various changes and modifications will be apparent to those skilled in the art. Therefore, unless otherwise such changes and modifications depart from the scope of the present invention hereinafter defined, they should be construed as being included therein.

1. A laminate comprising a resin layer (A) and a conductive layer (B), wherein
the resin layer (A) is stretchable, and
the conductive layer (B) is buried in the resin layer (A) and exposed on any one surface of the resin layer (A).

2. The laminate according to claim 1, wherein the conductive layer (B) contains silver or copper.

3. The laminate according to claim 1, wherein the conductive layer (B) is non-stretchable.

4. The laminate according to claim 1, wherein a tensile stress of the resin layer (A) at 50% elongation is 0.5 MPa or more and 100 MPa or less.

5. The laminate according to claim 1, wherein the resin layer (A) has a percentage elongation after fracture of 50% or more and 700% or less.

6. The laminate according to claim 1, further comprising a second conductive layer (B′) buried in the resin layer (A) and exposed on a surface of the resin layer (A) opposite to a surface where the conductive layer (B) is exposed.

7. The laminate according to claim 6, wherein the second conductive layer (B′) is non-stretchable.

8. The laminate according to claim 1, further comprising a second conductive layer (B′) formed on a surface of the resin layer (A) on a side opposite to a surface where the conductive layer (B) is exposed.

9. The laminate according to claim 8, wherein the second conductive layer (B′) is stretchable.

10. The laminate according to claim 8, wherein at least a part of the conductive layer (B) and at least a part of the second conductive layer (B′) are conductive.

11. The laminate according to claim 8, further comprising a second resin layer (A′) on the resin layer (A), wherein
the second conductive layer (B′) is buried in the second resin layer (A′), and
the laminate further includes a third conductive layer (B″) formed on a surface of the second resin layer (A′) on a side opposite to a surface in which the conductive layer (B′) is buried.

12. The laminate according to claim 1, further comprising a support substrate (C).

13. The laminate according to claim 1, further comprising a protective layer (D).

14. An electronic device comprising:
the laminate according to claim 1; and
an electronic component.
